(19) United States
(12) Patent Application Publication
(10) Pub. No.: US 2025/0145049 A1
(43) Pub. Date: May 8, 2025

(54) BATTERY MANAGEMENT DEVICE

(71) Applicant: TOYOTA JIDOSHA KABUSHIKI KAISHA, Toyota-shi (JP)

(72) Inventor: Makoto MURAKAMI, Toyota-shi (JP)

(73) Assignee: TOYOTA JIDOSHA KABUSHIKI KAISHA, Toyota-shi (JP)

(21) Appl. No.: 18/790,168

(22) Filed: Jul. 31, 2024

(30) Foreign Application Priority Data
Nov. 7, 2023 (JP) 2023-190223

(51) Int. Cl. B60L 58/12; G01R 31/367; G01R 31/3842; H02J 7/00

(52) U.S. Cl. CPC B60L 58/12; G01R 31/367; G01R 31/3842; H02J 7/0048

(57) ABSTRACT

A battery management device for controlling a charge of a battery during parking of a vehicle includes: an acquisition unit that acquires information on a dark current flowing out of the battery every time a predetermined timing comes; a prediction unit that predicts a charge consumed by the battery from a timing of current time to a timing of next time based on the information on the dark current acquired by the acquisition unit; an estimation unit that estimates a charge of the battery when the timing of the next time comes based on the consumed charge of the battery predicted by the prediction unit; and a requesting unit that requests charging of the battery when the charge of the battery estimated by the estimation unit is equal to or less than a predetermined threshold value.

### CROSS-REFERENCE TO RELATED APPLICATION

This application claims priority to Japanese Patent Application No. 2023-190223 filed on Nov. 7, 2023, incorporated herein by reference in its entirety.

### BACKGROUND

### 1. Technical Field

The present disclosure relates to a battery management device that manages charging and discharging of a battery installed in a vehicle.

### 2. Description of Related Art

Japanese Unexamined Patent Application Publication No. 2011-084859 (JP 2011-084859 A) discloses a system for managing charging control for an electrified vehicle that is parked in a parking facility. In this system, a battery of the electrified vehicle is fully charged by a parking unit provided in the parking facility. A battery charge of the electrified vehicle following being fully charged is then periodically monitored. It is described that in this system, recharging of the battery is performed by detecting that the battery charge has decreased to a predetermined charge or lower.

### SUMMARY

When a lithium ferrophosphate battery (LFP battery) is used for a battery of a vehicle, it is desirable to perform charging and discharging in a region in which the storage rate is constantly high (high SOC region) in order to prevent cycling degradation. However, in the technology described in JP 2011-084859 A, charging control of a plurality of vehicles having different types of batteries installed is performed uniformly while parked, and accordingly optimal control for the batteries may not be performed in some cases. Thus, there is room for further study on a method of optimally controlling charging and discharging of batteries of vehicles.

The present disclosure has been made in view of the above problems, and an object thereof is to provide a battery management device that is capable of controlling charging and discharging of batteries of parked vehicles in a high SOC region.

In order to solve the above problem, an aspect of the technique of the present disclosure is
a battery management device that controls a charge of a battery of a vehicle that is parked, the battery management device including
an acquisition unit that acquires information regarding a dark current flowing out of the battery, each time a predetermined timing arrives,
a prediction unit that predicts a charge that is consumed by the battery from a timing of current time until a timing of next time arrives, based on the information regarding the dark current acquired by the acquisition unit,
an estimation unit that estimates a charge of the battery for when the timing of the next time arrives, based on a consumed charge of the battery predicted by the prediction unit, and
a requesting unit that requests charging of the battery when the charge of the battery estimated by the estimation unit is no greater than a predetermined threshold value.

According to the battery management device of the present disclosure, necessity of charging the battery is determined based on the consumed charge of the battery predicted from the dark current in an individual vehicle while parked, and accordingly the control of charging and discharging the battery can be performed in the high SOC region at all times.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a functional block diagram of a battery management device and a peripheral portion thereof according to an embodiment of the present disclosure;

FIG. 2 is a diagram for explaining a use area of an auxiliary battery; and

FIG. 3 is a flowchart illustrating a processing procedure of charge/discharge control of an auxiliary battery executed by the battery management device.

### DETAILED DESCRIPTION OF EMBODIMENTS

The battery management device of the present disclosure predicts a tendency of a decrease in the charge of the auxiliary battery during parking based on a dark current flowing out from the auxiliary battery to the load, and charges the auxiliary battery by the high-voltage battery before the charge of the auxiliary battery becomes equal to or less than a reference value. As a result, charge/discharge control of the auxiliary battery can be performed in the high SOC range at all times.

Hereinafter, an embodiment of the present disclosure will be described in detail with reference to the drawings.

### EMBODIMENT

### Configuration

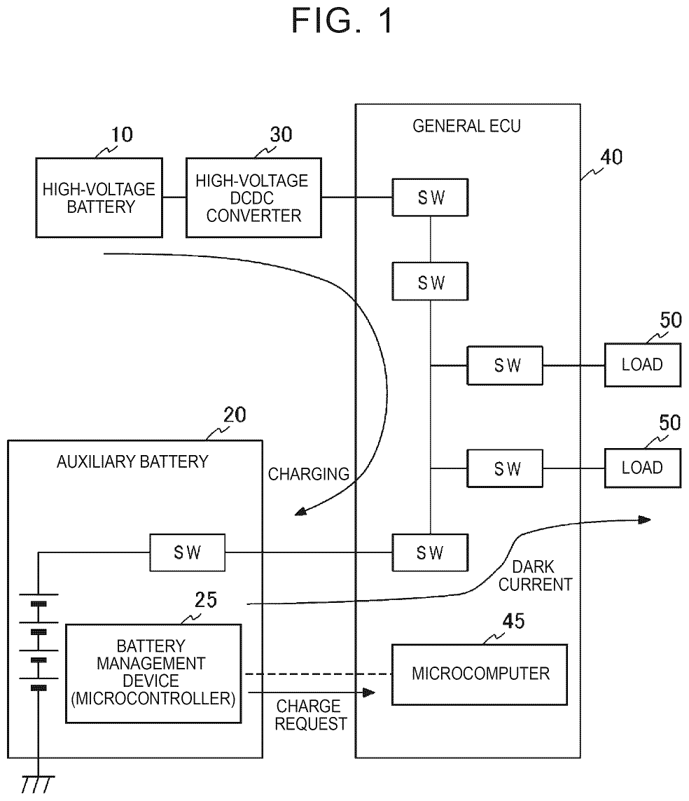

FIG. 1 is a functional block diagram of a battery management device 25 and a peripheral portion thereof according to an embodiment of the present disclosure. The functional block illustrated in FIG. 1 includes a high-voltage battery 10, an auxiliary battery 20, a high-voltage DCDC converter 30, an overall ECU 40, and a plurality of loads 50. In FIG. 1, a power line through which power is transmitted and received is indicated by a solid line, and a signal line through which a request instruction flows is indicated by a broken line.

The configuration shown in FIG. 1 can be mounted on electrified vehicle such as hybrid electric vehicle (HEV), plug-in hybrid electric vehicle (PHEV), and battery electric vehicle (BEV).

The high-voltage battery 10 is a secondary battery configured to be chargeable and dischargeable, such as a lithium-ion battery. The high-voltage battery 10 can supply the electric power stored therein to the loads 50 and the auxiliary battery 20 via the high-voltage DCDC converter 30 and the plurality of switching SW. In addition, the high-voltage battery 10 may store electric power output by a generator (not shown) such as an alternator. In electrified vehicle, for example, the driving battery corresponds to the high-voltage battery 10.

The auxiliary battery 20 is a secondary battery configured to be chargeable and dischargeable, such as a LFP cell. The auxiliary battery 20 stores electric power outputted from the high-voltage battery 10 via the high-voltage DCDC converter 30 and supplies the electric power stored therein to the loads 50 via a plurality of switching SW. In addition to the battery cells connected in series, the auxiliary battery 20 includes a battery management device 25 and a switching SW that can be electrically connected under the control of the battery management device 25. In order to reduce power consumption during parking, the auxiliary battery 20 alternately transitions between a wake-up state in which all functions are activated and a sleep state in which some functions are stopped at a certain cycle.

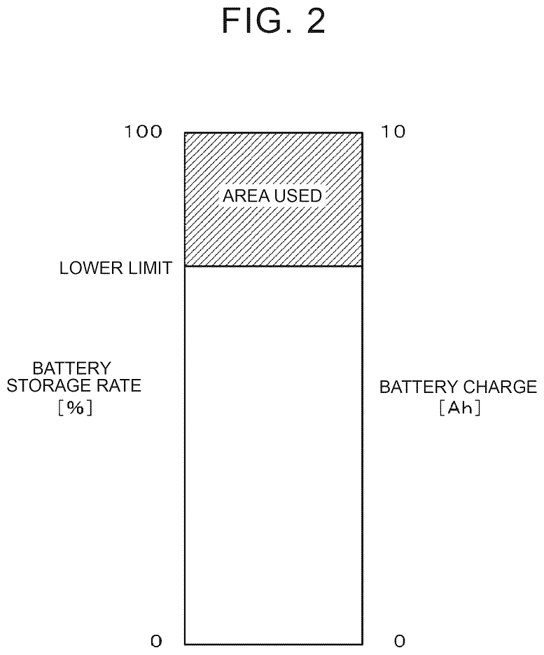

In the auxiliary battery 20, as shown in FIG. 2, the “usage area” which is the amount of electric power of the battery that is allowed to be used by discharging is determined in advance as the lower limit of the charge [Ah] of the battery or the storage rate (SOC) [%] of the battery. The lower limit value is set to, for example, a value capable of suppressing degradation of the auxiliary battery 20 due to the charge/discharge process to a content required for electrified vehicle.

The battery management device 25 is a configuration for managing the state of the auxiliary battery 20 including the charge/discharge control of the auxiliary battery 20, and is typically a microcomputer. The battery management device 25 can acquire information of dark current flowing out from the auxiliary battery 20 to the plurality of loads 50 (acquisition unit), predict the charge consumed by the auxiliary battery 20 based on the acquired dark current information (prediction unit), estimate the charge (remaining charge) or the storage rate of the auxiliary battery 20 based on the predicted consumed charge of the auxiliary battery 20 (estimation unit), and request charging of the auxiliary battery 20 based on the estimated charge or the storage rate of the auxiliary battery 20 (requesting unit). The acquisition of the dark current information and the prediction of the charge (storage rate) of the auxiliary battery 20 can be performed by using a detection value of a detection device (a voltage sensor, a current sensor, a temperature sensor, or the like) included in the auxiliary battery 20.

The high-voltage DCDC converter 30 is provided between the high-voltage battery 10 and the overall ECU 40. The high-voltage DCDC converter 30 is a voltage converter for converting a voltage of the high-voltage battery 10 to be inputted into a voltage required for the auxiliary battery 20 and the load 50, and outputting the voltage to the respective components via the overall ECU 40. The high-voltage DCDC converter 30 may be, for example, a step-down type DCDC converter that steps down the voltage of the high-voltage battery 10 and outputs it to the auxiliary battery 20 or the load 50.

The overall ECU 40 is a configuration (ECU: Electronic Control Unit) for controlling power exchange between the high-voltage battery 10, the auxiliary battery 20, and the plurality of loads 50. The overall ECU 40 includes a microcomputer 45 and a plurality of switching SW that can be electrically connected under the control of the microcomputer 45.

The microcomputer 45 is communicably connected to the battery management device 25 of the auxiliary battery 20 via a CAN or the like. The microcomputer 45 performs control to charge the electric power of the high-voltage battery 10 to the auxiliary battery 20 in response to a charging request (described later) output from the battery management device 25.

The loads 50 are in-vehicle devices that operate with electric power supplied from the high-voltage battery 10 or electric power supplied from the auxiliary battery 20 via the high-voltage DCDC converter 30. The number of loads mounted on the vehicle is not limited to the number shown in FIG. 1.

### Control

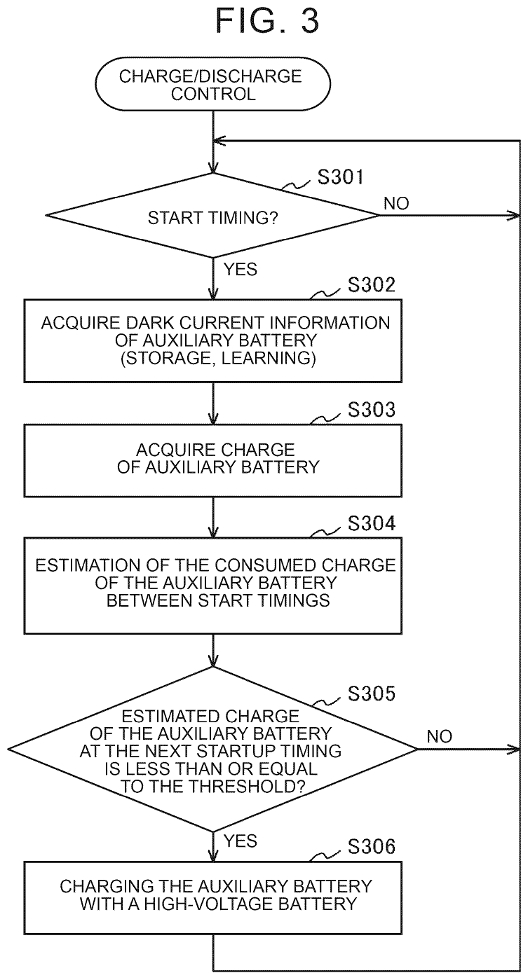

Next, the control performed by the battery management device 25 according to the present embodiment will be described with further reference to FIG. 3. FIG. 3 is a flowchart for explaining a processing procedure of charge/discharge control of the auxiliary battery 20 executed by the battery management device 25.

The charging/discharging control of the auxiliary battery 20 illustrated in FIG. 3 is repeatedly performed until electrified vehicle is in the parking state (IG-OFF) and electrified vehicle is in the activation state (IG-ON).

### S301

The battery management device 25 determines whether or not it is a timing for starting a predetermined function for performing charge/discharge control of the auxiliary battery 20. The start timing can be arbitrarily set, such as a certain cycle. When the battery management device 25 determines that it is the start-up timing (S301, Yes), the process proceeds to S202 after starting a predetermined function.

### S302

The battery management device 25 acquires the dark current flowing from the auxiliary battery 20 to the plurality of loads 50 while electrified vehicle is parked. The dark current is a current consumed by a function related to authentication of an electronic key or the like. The acquired dark current information is sequentially stored in a storage unit or the like (not shown), and necessary learning is performed. When the dark current of the auxiliary battery 20 is acquired by the battery management device 25, the process proceeds to S303.

### S303

The battery management device 25 acquires the charge (or storage rate) of the present auxiliary battery 20. This charge (or storage rate) can be derived from a detection value of a detection device included in the auxiliary battery 20. When the charge (or the storage rate) of the auxiliary battery 20 is acquired by the battery management device 25, the process proceeds to S304.

### S304

The battery management device 25 predicts the charge consumed by the auxiliary battery 20 during the start-up timing based on the dark current of the auxiliary battery 20 acquired by S302. The period between the start timings is a period between the current start timing at which the information on the dark current of the latest auxiliary battery 20 is acquired and the next start timing. When the start timing arrives at a certain cycle, the time interval of this cycle is between the start timings.

As an example, the consumed charge Cc [Ah] of the auxiliary battery 20 during the start-up timing of the time T [h] can be predicted by the following equation (1) using the dark current I [A] of the auxiliary battery 20 at this time. Alternatively, in order to improve the prediction accuracy, instead of the dark current I, the average value AVE_I [A] of the dark currents of the plurality of auxiliary batteries 20 obtained so far can also be used to predict by the following equation (2).

$$Consumed charge Cc = Dark current I \times time T \qquad ( 1 )$$

$$Consumed charge Cc = Average dark current AVE\_I \times time T \qquad ( 2 )$$

When the battery management device 25 predicts the consumed charge of the auxiliary battery 20 between the start-up timings, the process proceeds to S305.

### S305

The battery management device 25 determines whether or not the charge (or the storage rate) of the auxiliary battery 20 estimated at the next start-up timing is equal to or less than a predetermined threshold value. This determination is made to determine whether or not there is a possibility that the auxiliary battery 20 will consume the charge of the unfavorable use area with respect to deterioration before the next start-up timing arrives. Therefore, the lower limit value of the charge or the lower limit value of the storage rate (SOC) of the auxiliary battery 20 described above is used as the predetermined threshold value.

The estimated charge Ce (or estimated storage rate) of the auxiliary battery 20 can be obtained by subtracting the charge Cc [Ah] consumed by the auxiliary battery 20 by the next start-up timing predicted by the above S304 from the present charge Cp [Ah] (or storage rate [%]) of the auxiliary battery 20 acquired by the above S303, as shown in Equation (3) below.

$$Estimated charge Ce = Present charge Cp - Consumed charge Cc \qquad ( 3 )$$

Further, in order to improve the estimation accuracy, the mean value AVE_Cc [Ah] of the consumed charge of the plurality of auxiliary batteries 20 predicted so far may be used instead of the consumed charge Cc (Equation (4) below). Alternatively, the sum TOTAL_Cc [Ah] of the consumed charges of the plurality of auxiliary batteries 20 predicted after the auxiliary battery 20 reaches the full charge Cmax may be obtained by subtracting the sum from the full charge Cmax (Equation (5) below).

$$Estimated charge Ce = Present charge Cp - Mean Consumed charge AVE\_Cc \qquad ( 4 )$$

$$Estimated charge Ce = Full Charge C max - Total Consumed charge TOTAL\_Cc \qquad ( 5 )$$

When the battery management device 25 determines that the estimated charge (or estimated storage rate) of the auxiliary battery 20 at the time of the next start-up timing is equal to or less than the predetermined threshold (S305, Yes), the process proceeds to S306. On the other hand, when the battery management device 25 determines that the estimated charge (or estimated storage rate) of the auxiliary battery 20 at the time of the next start-up timing does not fall below a predetermined threshold (S305, No), the process returns to S301.

### S306

The battery management device 25 performs charging of the auxiliary battery 20 by electric power of the high-voltage battery 10. This charging is performed by the battery management device 25 transmitting a charging request from the high-voltage battery 10 to the auxiliary battery 20 to the overall ECU 40. The overall ECU 40 that has received the charge request controls (instructs) the high-voltage DCDC converter 30 to exchange electric power between the high-voltage battery 10 and the auxiliary battery 20. When the auxiliary battery 20 is charged by the electric power of the high-voltage battery 10 by the battery management device 25, the process returns to S301.

### Operations and Effects

According to the battery management device 25 according to the embodiment of the present disclosure described above, the charge consumed by the auxiliary battery 20 during a predetermined period is predicted based on the dark current flowing out from the auxiliary battery 20 during parking. The battery management device 25 estimates a change in the battery charge based on the predicted consumed charge of the auxiliary battery 20, and determines whether the charge of the auxiliary battery 20 is equal to or less than a threshold value that affects deterioration in the near future. When it is determined that the charge of the auxiliary battery 20 is expected to be equal to or less than the threshold in the near future, the auxiliary battery 20 is charged.

By this control, since the auxiliary battery 20 is charged in advance so as not to be equal to or less than the thresholds, it is possible to control the charging and discharging of the auxiliary battery 20 in the high SOC area at all times. Therefore, the progress of the deterioration of the auxiliary battery 20 can be suppressed.

Further, according to the battery management device 25 of the present embodiment, by predicting the consumed charge of the auxiliary battery 20 based on the average value (learning) of the dark current, it is possible to improve the prediction accuracy even when the dark current can be acquired only at the start-up timing. Further, the estimation accuracy can be improved by estimating the charge of the auxiliary battery 20 based on the average value of the consumed charge of the auxiliary battery 20.

Further, according to the battery management device 25 of the present embodiment, the charge is determined by using the consumed charge of the auxiliary battery 20. Therefore, the battery management device 25 according to the present embodiment can also be applied to a battery in which it is difficult to specify the storage rate SOC by the voltage, a LFP cell having a flat area (section) in a so-called SOC-OCV property, or the like.

In some of the services provided during parking, there may be a service that consumes a large amount of dark current even when the auxiliary battery 20 is in the sleep state. In such a case, if a dark current of a certain value or more flows, the auxiliary battery 20 may be activated without waiting for the activation timing (wake-up state). At this time, the estimation of the consumed charge of the auxiliary battery 20 and the estimation of the charge may be performed from the elapsed time from the previous startup timing and the current dark current.

Although an embodiment of the present disclosure has been described above, the present disclosure can be regarded as not only the above-described battery management device but also a method executed by a battery management device including a processor and a memory, a program of the method, a computer-readable non-transitory recording medium storing the program, or a vehicle equipped with a battery management device.

The battery management device of the present disclosure can be used for a vehicle including a high-voltage battery and an auxiliary battery.

What is claimed is:

1. A battery management device that controls a charge of a battery of a vehicle that is parked, the battery management device comprising:
an acquisition unit that acquires information regarding a dark current flowing out of the battery, each time a predetermined timing arrives;
a prediction unit that predicts a charge that is consumed by the battery from a timing of current time until a timing of next time arrives, based on the information regarding the dark current acquired by the acquisition unit;
an estimation unit that estimates a charge of the battery for when the timing of the next time arrives, based on a consumed charge of the battery predicted by the prediction unit; and
a requesting unit that requests charging of the battery when the charge of the battery estimated by the estimation unit is no greater than a predetermined threshold value.

2. The battery management device according to claim 1, wherein the prediction unit predicts a consumed charge of the battery, from the timing of the current time until the timing of the next time arrives, based on an average value of a plurality of the dark currents acquired in past by the acquisition unit.

3. The battery management device according to claim 1, wherein the estimation unit estimates the charge of the battery for when the timing of the next time arrives, based on an average value of consumed charges of a plurality of the batteries predicted in past by the prediction unit.

4. The battery management device according to claim 1, wherein the predetermined timing is determined by a certain cycle.
